(19) United States
(12) Patent Application Publication
(10) Pub. No.: US 2006/0064612 A1
(43) Pub. Date: Mar. 23, 2006

(54) Integrated circuit arrangement, integrated circuit, matrix array of circuits and electronic device

(75) Inventors: Alan G Knapp, Crawley (GB); Steven C Deane, Redhill (GB)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., BA Eindhoven (NL)

(21) Appl. No.: 10/537,516

(22) PCT Filed: Nov. 21, 2003
(86) PCT No.: PCT/IB03/05321

§ 371 Date: Jun. 3, 2005

(30) Foreign Application Priority Data
Dec. 6, 2002 (GB) 0228479.2

(51) Int. Cl. G01R 31/28

(52) U.S. Cl. 714/724

(57) ABSTRACT

An IC arrangement (200) has a plurality of IC modules (220a, 220b), the individual IC modules (220a, 220b) being coupled between a first power line (202) and a second power line (204) via a voltage generator (240a, 240b). The voltage generators (240a, 240b) are powered via the first power line (202) and the second power line (204) and are arranged to regenerate a reference voltage on a reference power line (106) for providing the IC modules (220a, 220b) with the regenerated voltage on respective internal power lines (222a, 222b). A feedback loop (242a, 242b) from the internal power lines (222a, 222b) to the voltage generator (240a, 240b) ensures that the voltage on the internal power lines (222a, 222b) remains substantially constant, even if substantial current fluctuations on the first power line (202), the second power line (204) or the internal power line (222a, 222b) occur. The IC arrangement (200) is particularly suitable as a driver circuit for a matrix array device.

The invention relates to an integrated circuit arrangement having a plurality of integrated circuit modules as well as to a matrix array device and an electronic device having such an integrated circuit arrangement.

Integrated circuit (IC) arrangements typically comprise a number of interconnected IC modules. Such a module may be a complete IC or a discrete building block of an IC, for example an IP core. The IC modules in the IC arrangement may be interconnected for functional collaboration or may each perform an independent task. In both cases, the IC modules of the IC arrangement are likely to be coupled between a first power line and a second power line, the power lines being arranged to provide a voltage difference over the IC modules for enabling the provision of an adequate current to the IC modules in order to enable the IC modules to perform their designated tasks.

Typically, the desired functional behaviour of the IC modules relies upon the correct voltage being applied over the IC modules. In some application domains of the IC arrangement, the guaranteed provision of a correct voltage is not a trivial matter. An application domain where this for instance applies to is the area of driver circuitry, where the IC modules of the IC arrangement are used to drive a predefined value into discrete electronic components, for example cells of a matrix array device like a liquid crystal display (LCD) device. In such arrangements, an IC from the plurality of IC modules is coupled to at least one conductor of the matrix array for driving a predefined signal value onto the at least one conductor.

The ongoing increase of the dimensions of the matrix array device can lead to serious complications in maintaining a stable voltage difference over the IC modules of the IC arrangement, for instance because the IC arrangements involved in driving the matrix array have to be able to generate larger currents to maintain the desired voltage over the driver IC modules. If this cannot be realized in a sufficient way, different IC modules can experience different voltages, which is an unwanted effect. This is especially the case for matrix array display devices, for example LCD or light emitting diode (LED) devices based on matrix arrays, because such voltage differences can cause observable defects in the output of the display device, for example difference in the brightness between two lines of the displayed picture, which is interpreted as a deterioration of the picture quality by the viewer and should therefore be avoided.

One probable cause of such deterioration is being tackled by an invention disclosed in Japanese Patent Application JP 10070821, where a driver IC of an LCD device is coupled to an output of an operational amplifier (opamp) via a series resistor. The opamp has its positive, or non-inverting, input coupled to a voltage divider circuit, and its negative, or inverting, input coupled to a feedback loop from its own output. The opamp is designed in such a fashion that fluctuations in the voltage waveform caused by fluctuations in the input impedance of the driver IC that originate from large variations in the load of the driver IC, are being suppressed.

However, voltage variations over the driver IC can also be caused by the finite impedance of the power lines of the IC arrangement, for which the arrangement disclosed in the aforementioned Japanese patent application does not necessarily provide a remedy. Such variations can for instance be caused by the fact that the matrix array of the device, that is, the regular collection of conductors and matrix cells, for instance LC cells and/or transistors like thin-film transistors, represent a large collection of capacitances, which are regularly being charged and discharged depending on the signals that are being driven onto the conductors by the IC modules of the IC arrangement or IC arrangements. These effects can give rise to substantial currents through the conductors, especially when the matrix array is large, and/or the IC arrangement is mounted on a non-conductive substrate, for example glass. Because the power lines of the IC arrangement have a finite impedance, these currents can lead to neighbouring driver ICs experiencing different voltages, thus producing unwanted artefacts. Such artefacts may include deterioration of a display image, because the voltage variations between neighbouring ICs can cause an unacceptable change in brightness between the display lines driven by neighbouring ICs, especially when these voltages are being used in the device as reference voltages.

Amongst others, it is an object of the present invention to provide an integrated circuit arrangement that is at least relatively insensitive to voltage fluctuations over the power lines that are coupled to the IC modules of the IC arrangement.

Amongst others, it is another object of the present invention to provide an integrated circuit is at least relatively insensitive to voltage fluctuations over the power lines of the IC.

Amongst others, it is a further object of the present invention to provide a matrix array device that has improved operational characteristics.

Amongst others, it is yet a further object of the invention to provide an electronic device that benefits from the presence of an improved IC arrangement.

The invention provides for an integrated circuit arrangement comprising a plurality of integrated circuit modules, a first power line, a second power line, a reference power line, an integrated circuit module from the plurality of circuit modules comprising an internal power line and a circuit module portion coupled between the first power line and the internal power line, the integrated circuit arrangement further comprising a voltage generator coupled between the first power line and the second power line, the voltage generator having a control terminal coupled to the reference power line and an output coupled to the internal power line. According to the invention, an integrated circuit is coupled to an internal, freshly generated power line rather than a global power line, with the freshly generated, or regenerated, power line being coupled to an output of a voltage generator, which is powered by the first and second power line, but is responsive to a reference power line of the integrated circuit arrangement. By running small or even negligible currents through the reference power line, its voltage will be the substantially the same for all IC modules in the IC arrangement and, consequently, the respective voltage generators will generate substantially similar voltages on the respective internally generated power lines, which will make the functional behaviour of the IC modules that have their own internally generated power line much less sensitive to current fluctuations through the power lines of the IC arrangement.

In an embodiment, the integrated circuit module from the plurality of integrated circuit modules further comprises a second circuit module portion coupled between the first power line and the second power line.

An IC module may comprise a portion, the correct functioning of which is sensitive to current fluctuations on the first and second power lines, and a portion, the correct functioning of which is relatively insensitive to such fluctuations. It is advantageous to couple the former portion to the voltage generator and the latter portion directly to the first and second power lines, because this will reduce the load on the voltage generator, which allows for more compact, for example smaller, voltage generator designs.

In another embodiment, the voltage generator comprises an operational amplifier having a non-inverting input comprising the control terminal and an inverting input coupled to the internal power line. An operational amplifier is particularly suitable as a voltage generator, because of its ability to produce stable voltages on its output, that is the internal voltage line even when its power terminals, that is the first power line and the second power line exhibit substantial voltage fluctuations. By connecting the opamp as a voltage follower, that is connecting the reference voltage to its non-inverting input and feeding the internal power line back to its inverting input, the opamp can also compensate for current fluctuations on the internal power line, thus effectively regenerating and maintaining a very stable reference voltage on the internal power line.

In yet another embodiment, the voltage generator comprises a current source coupled between the first power line and the internal power line; and a transistor coupled between the internal power line and the second power line, the transistor having a gate comprising the control terminal.

This arrangement is not as robust as the aforementioned opamp arrangement, but has the advantage that uses a smaller area of silicon and it is cheaper to implement. Typically, as long as the voltage variations on the second power line do not exceed the reference voltage, this arrangement is capable of effectively cancelling the voltage fluctuations. Even if the voltage fluctuations are larger than the voltage difference between the reference line and the second power line, the fluctuations will still be dampened, which will be sufficient compensation in situations where only large fluctuations cause unacceptable detrimental effects.

The invention further provides for an integrated circuit, comprising a first power line connector, a second power line connector, a reference power line connector, an internal power line, a circuit portion coupled between the first power line connector and the internal power line, and a voltage generator coupled between the first power line connector and the second power line connector, the voltage generator having a control terminal coupled to the reference power line connector (406) and an output coupled to the internal power line. Such an IC can be used as a separate driver circuit or as a building block in the IC arrangement of the invention. Other applications, where a well-defined, stable voltage is of the essence for the correct functioning of the IC, for example self-timed circuits, are also feasible. The voltage generator, which again may be an opamp, a combination of a current source and a transistor or well-known equivalents thereof, ensures that the functional performance of the IC is less sensitive to voltage fluctuations on the connections of the first and the second power line than in ICs where such measures are absent.

The invention further provides for a matrix array device comprising a first set of conductors, a second set of conductors, the conductors from the second set of conductors being substantially perpendicularly oriented to the conductors from the first set of conductors, a plurality of matrix elements, each matrix element from the plurality of matrix elements being coupled between a conductor from the first set of conductors and a conductor from the second set of conductors, and a first integrated circuit arrangement comprising a plurality of integrated circuit modules, a first power line, a second power line, a reference power line, an integrated circuit module from the plurality of circuit modules comprising an internal power line and a circuit module portion coupled between the first power line and the internal power line, the circuit portion having an output coupled to a conductor from the first set of conductors, the first integrated circuit arrangement further comprising a voltage generator coupled between the first power line and the second power line, the voltage generator having a control terminal coupled to the reference power line and an output coupled to the internal power line.

The present invention is particularly suitable for application in the area of matrix array devices, for example active matrix LCD displays and active matrix polymer-LED or organic-LED displays, especially when such devices are mounted on an insulating surface. The charging and discharging of the capacitances of the matrix array cells, for example the thin film transistors and the capacitors in a LC cell, as well as the cross-coupling capacitances between the conductors of the first and second set, that is the row and column driver conductors, can cause large fluctuations in currents. By driving the matrix array device with an IC arrangement of the present invention, the detrimental consequences of these fluctuations are being reduced or even avoided. The IC arrangement may be a separate, discrete arrangement bonded to the matrix array, or alternatively may be integrated in the matrix array by realizing the IC arrangement in the same technology as the matrix array, for example by using thin film transistors.

Preferably, the matrix array device further comprises a second integrated circuit arrangement, the second integrated circuit arrangement comprising a plurality of integrated circuit modules; a first power line; a second power line; a reference power line; an integrated circuit module from the plurality of circuit modules comprising an internal power line; and a circuit portion coupled between the first power line and the internal power line, the circuit portion having an output coupled to a conductor from the second set of conductors; the second integrated circuit arrangement further comprising a voltage generator coupled between the first power line and the second power line, the voltage generator having a control terminal coupled to the reference power line and an output coupled to the internal power line.

If both sets of conductors are driven by an IC arrangement of the present invention, the effects of the current fluctuations on the conductors from both sets is compensated for.

In an embodiment, the matrix array device is a display device. Display devices typically require a well-defined state of the picture elements, because the human eye is very sensitive to certain artefacts in the picture, one of them being brightness differences between neighbouring lines formed by a number of picture elements or groups of lines in the picture. Especially matrix array display devices like active matrix LCDs and active matrix LED displays are very sensitive to such artefacts, because of the large area of the display device and the insulating substrate that is usually used to produce such devices, which can lead to large fluctuations in currents flowing through the conductors of the matrix array device. By applying the present invention to a matrix array display, an improved picture quality can be obtained, because the brightness differences that originate from current fluctuation induced voltage differences between the various driver circuits can be reduced or even avoided.

The invention further provides for an electronic device comprising an integrated circuit arrangement according to the present invention and having power supply means coupled to the first power line, the second power line and the reference power line of the integrated circuit arrangement.

Integration of an IC arrangement according to the present invention improves the stability and the reliability of the electronic device. This can be particularly advantageous in application domains where the electronic device is required to have very stable operation characteristics. One particular example of such an application domain is that of display devices, for example monitors, televisions and hand-held devices including display screens, where disturbances in the performance of the display part of the electronic device will have a direct impact on the user valuation of the performance of the electronic device as a whole.

The invention is described in more detail and by way of non-limiting examples with reference to the accompanying drawings, wherein:

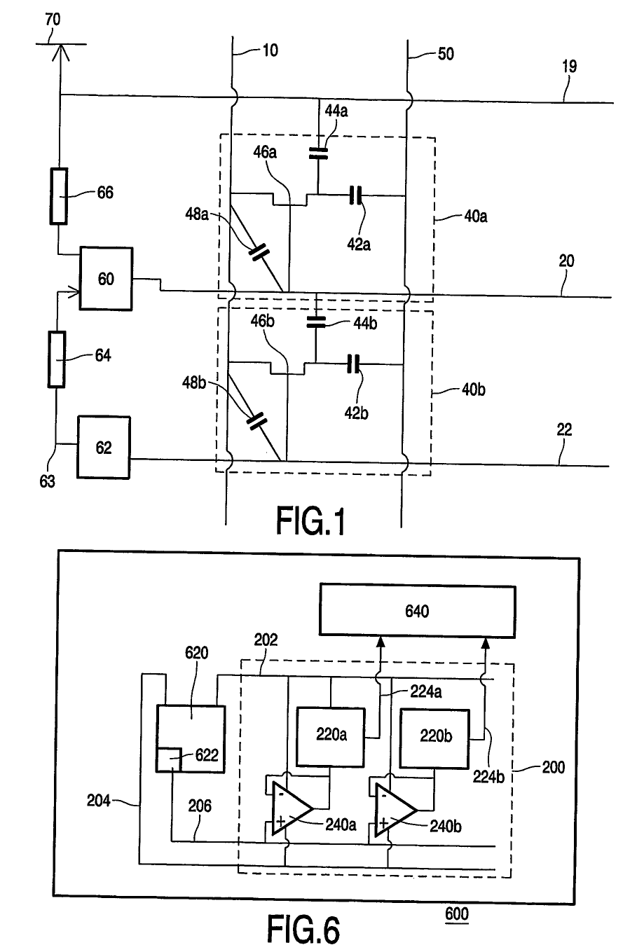

FIG. 1 depicts a schematic representation of a part of a matrix array device coupled to an integrated circuit arrangement;

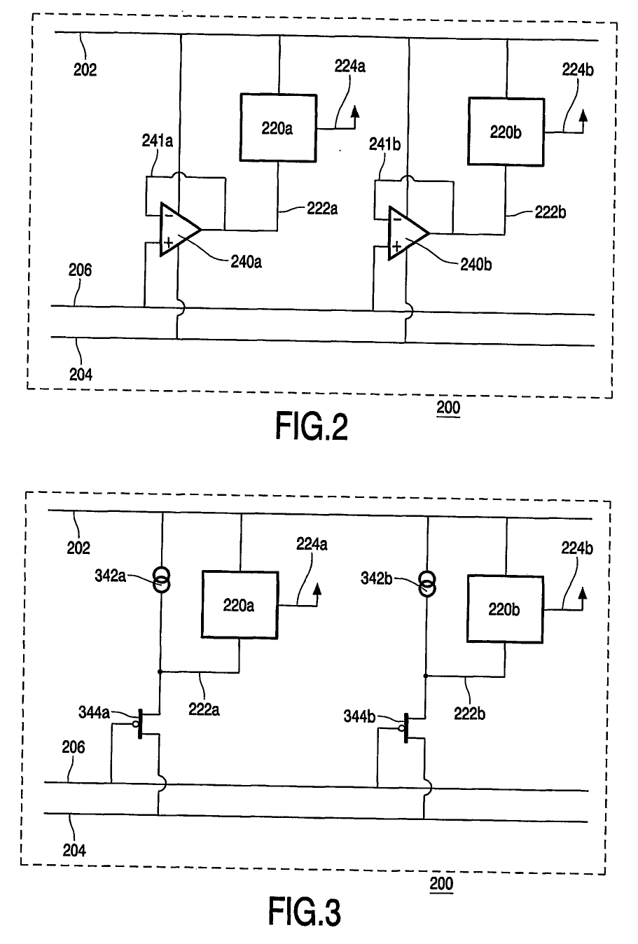

FIG. 2 depicts an embodiment of an integrated circuit arrangement according to the present invention;

FIG. 3 depicts another embodiment of an integrated circuit arrangement according to the present invention;

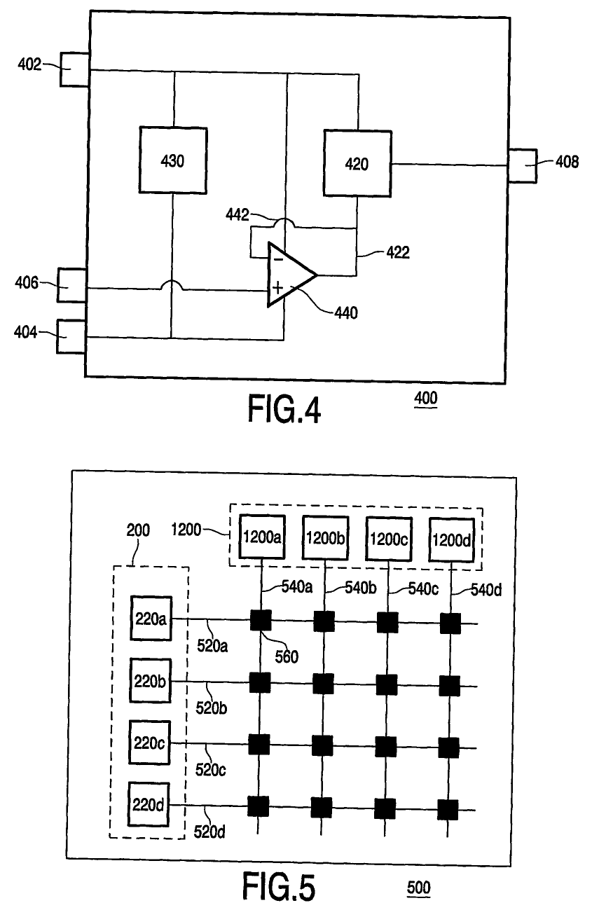

FIG. 4 depicts an embodiment of an integrated circuit according to the present invention;

FIG. 5 depicts a matrix array device according to the present invention; and

FIG. 6 depicts an electronic device according to the present invention.

In FIG. 1, a part of a matrix array device is shown by means of a schematic representation of liquid crystal (LC) pixels 40a and 40b, which are both coupled to column conductor 10 and are coupled to row conductors 20 and 22 respectively. The LC pixels 40a and 40b each comprise an amount of LC material, represented by the respective capacitors 42a and 42b, the respective storage capacitors 44a and 44b and the respective thin film transistors 46a and 46b. It is emphasized that the storage capacitors 44a and 44b are respectively coupled to neighbouring row conductors 19 and 20 by way of non-limiting example only. Other arrangements, for instance an arrangement in which the storage capacitors are coupled to dedicated capacitance lines, are also feasible.

The gates of the thin film transistors 46a and 46b are controlled by the respective row conductors 20 and 22. The LC material is coupled between the column conductor 10 and the common electrode 50. Row conductor 20 is coupled to driver IC 60, and row conductor 22 is coupled to driver IC 62, both driver ICs forming a part of an IC arrangement. The driver ICs 60 and 62 are coupled to the system ground potential 70 via power line 63. Power line 63, which serves as a reference voltage to the pixels of the matrix array device has a finite impedance, as indicated by resistor 64 between driver IC 60 and driver IC 62, and resistor 66 between the system ground potential 70 and the driver circuit 60.

In operation, LC pixel 40a will receive data via its column conductor 10. The data is enabled to be stored into the LC pixel 40a by enabling transistor 46a and storing the appropriate charges in the capacitors 42a and 44a. The transistor 46a is enabled by means of an addressing pulse at row conductor 20. Obviously, LC pixel 40b will be addressed in a similar fashion, but via row conductor 22. After the LC pixels 40a and 40b have been addressed, they need to keep their information until the next addressing event takes place. This is complicated by the fact that the intercrossing sets of row and column conductors have mutual capacitances, which are schematically depicted by the capacitor 48a between row conductor 20 and column conductor 10, and capacitor 48b between row conductor 22 and column conductor 10. The continuous fluctuation of currents flowing through those sets of conductors resulting from the addressing of the LC display elements lead to a frequent charging and discharging of their mutual capacitances, which can give rise to substantial currents running through, for instance, the row conductors even when the LC pixels connected to these conductors are not being addressed.

Typically, such currents will be removed from the conductors via power line 63. However, since power line 63 has a finite impedance, as for instance modelled by resistor 64, a voltage difference will occur between driver ICs 60 and 62, and between row conductors 20 and 22. Consequently, the voltage between common electrode 41a and row conductor 20 will be different than the voltage between common electrode 41b and row conductor 22. Since these voltage differences define the brightness level of the respective LC pixels 40a and 40b, they can lead to observable differences in brightness between rows of pixels when the differences become large enough.

Similar problems can occur during the addressing of the pixels by the column conductors when the voltage applied to the column conductors deviates from the intended value as a result of the currents from the aforementioned charging and discharging of the mutual capacitances flowing through the reference power line not shown coupled to the column driver ICs not shown.

An exemplary IC arrangement according to the present invention that avoids the occurrence of such artefacts is shown in FIG. 2. IC arrangement 200 includes a first power line 202, a second power line 204 and a separate reference power line 206. The IC arrangement 200 further includes a plurality of IC modules, including a first IC module 220a and a second IC module 220b, which both are connected to the first power line 202, and have respective outputs 224a and 224b for providing time-dependent signals to a further application, for example an external device or another IC module. At this point, it is emphasized that in the context of this application, an IC module may be a discrete IC or a discrete IC building block with a well-defined function, for example an intellectual property (IP) core or a similar building block. Rather is than being directly coupled to second power line 204, the first IC module 220a is coupled to an internal power line 222a, and the second IC module 220b is coupled to an internal power line 222b. The internal power line 220a is coupled to an output of a first operational amplifier (opamp) 240a, whereas the internal power line 220b is coupled to an output of a second opamp 240b. First and second opamps 240a and 240b are being powered via their respective couplings to first power line 202 and second power line 204. The positive, or non-inverting, input of each of the opamps 240a and 240b is coupled to the reference power line 206. The negative, or inverting, input of opamp 240a is coupled to internal power line 222a via feedback loop 241a, and the negative, or inverting, input of opamp 240b is coupled to internal power line 222b via feedback loop 241b. The opamps 240a and 240b operate as a voltage generator for the respective internal power lines 222a and 222b.

In operation, a very small current will be run through the reference power line 206. Therefore, even though the reference power line has a finite impedance, all opamps will sense a substantially similar potential and will generate a substantially similar voltage on the internal power lines of the various IC modules in the IC arrangement 200, for example IC modules 220a and 220b. In addition, a well-known quality of opamps is that their output signals can be made largely insensitive to any fluctuations on their power-supplying terminals, that is fluctuations on first power line 202 and second power line 204 for first opamp 240a and second opamp 240b. In this case, this can be achieved by choosing a reference potential on the reference line that is slightly higher than the potential on the second power line 204 in case of the second power line 204 being the power line that is connected to the negative terminal of the power supply not shown, in which case the second power line 204 is the low voltage or ground power line. Obviously, if the second power line 204 were the high voltage power line, the potential on the reference power line 206 would be chosen just below this voltage. Consequently, the voltage generated on the internal power lines 222a and 222b is largely independent of fluctuations on first and second power lines 202 and 204.

Furthermore, voltage fluctuations on the internal power line 222a and 222b will be sensed by the opamps 240a and 240b via their respective feedback loops 241a and 241b. In case of a voltage drop due to drop in the current on one of these power lines, the responsible opamp will increase the current flow from the positive power line, for example first power line 202 to stabilize the voltage on the involved internal power line. Alternatively, if a voltage increase caused by an increase in the current on one of these power lines is sensed, the responsible opamp will sink the excess current to the negative power line, for example second power line 204, again to stabilize the voltage on the involved internal power line, without disturbing the voltage generation by another opamp in the IC arrangement 200, because of the aforementioned insensitivity of those opamps to fluctuations on their power terminals.

Now, when referring back to FIG. 1 and its detailed description, outputs 224a and 224b may be coupled to a collection of row or column conductors of a matrix array device. It will be understood that the brightness artefacts described in the detailed description of FIG. 1 can no longer occur, because the involved voltage differences are now being defined between the common electrode 50 and the respective internally regenerated power lines 224a and 224b of the IC modules 220a and 220b in the IC arrangement 200, which are much less sensitive to current fluctuations than the global reference power line 63 of the matrix array device depicted in FIG. 1.

At this point it is emphasized that the IC arrangement of the present invention may comprise more than one internally regenerated power line; it can be advantageous to have a plurality of such lines when a number of stable voltages have to be provided, this is for instance the case for a voltage divider column driver operating as a digital/analog converter in a matrix array device, where both the supply voltage as well as the ground potential should be well defined to ensure the correct voltage levels for the various output signals of the column driver. In such a case, a plurality of reference power lines, each coupled to an input of a separate voltage generator, may be provided to regenerate the various power lines at the respective outputs of the separate voltage generators. The following Figs will be described in back reference to FIG. 2 and its detailed description. Corresponding reference numerals will have similar meanings unless explicitly stated otherwise.

FIG. 3 shows an IC arrangement 200 in which the opamps 240a and 240b have been replaced by alternative voltage generating arrangement. In FIG. 3, the voltage generator includes a current source 342a coupled between the first power line 202 and the internal power line 222a to IC module 220a, and a transistor 344a having its source coupled to the internal power line 222a and the second power line 204, with its control terminal, that is its gate, coupled to the reference power line 206. Correspondingly, the internal power line 222b of IC module 220b is coupled to the first power line 202 via a current source 242b and to the second power line 204 via a transistor 344b, which has its control terminal, that is its gate, coupled to the reference power line 206.

In operation, if for instance the current on internal power line 222a drops, the voltage difference over the transistor 344a will decrease and the current flowing through the transistor 344a will decrease as well. In addition, the current source 342a will increase the current to the internal power line 222a, and as a consequence, the voltage over the internal power line 222 will be maintained. Alternatively, if the current on an internal power line 222 increases, the voltage difference over the transistor 344a will increase and a stronger current will run through the transistor towards the second power line 204, whereas the current source 342a would produce less current, thus also maintaining the potential of the internal power line 222a.

It will be appreciated by those skilled in the art that the embodiment of a voltage generator as shown in FIG. 3, that is the current source 342 combined with the transistor 344 is less robust than the embodiment shown in FIG. 2, that is the opamp 240. For instance, as soon as the current fluctuations on the second power line 204 exceed the voltage difference between the reference power line 206 and second power line 204, these fluctuations, albeit dampened, will lead to fluctuations in the potential of an internal power line 222. However, the embodiment shown in FIG. 3 is cheaper to implement and is an acceptable alternative in situations where these current fluctuations are small enough to not be reproduced on the internal power lines 222 of the IC arrangement 200.

At this point, it is stipulated that the current source 342a merely operates as a load for a source follower, and could also be replaced by a suitable resistor. In fact, any unity gain buffer amplifier design capable of producing a low impedance output at a voltage defined by a reference input signal would be a suitable design for a voltage generator for the internal power lines of the IC arrangement 200. Also, it should be understood by those skilled in the art that the integration of the aforementioned embodiments of IC arrangement 200 is useful in any application that may provide significant current fluctuations on outputs 224a and/or 224b. Also, not all IC modules 220 in the IC arrangement 200 have to be coupled to the power supply not shown via voltage generator; this is only advantageous for IC modules that have an output coupled to a part of a device that requires a stable voltage between one of its elements, for example a common electrode of the matrix array device of FIG. 1, and a power line of the IC arrangement 200.

The following Figs will be also described in back reference to FIG. 3 and its detailed description. Corresponding reference numerals will have similar meanings unless explicitly stated otherwise.

It can also be advantageous to integrate any of the previously described voltage generators into an IC module, for example a discrete IC. An example of such an IC is given in FIG. 4, where an opamp is used as an embodiment of a voltage generator by way of non-limiting example only. IC 400 has a first power line connector 402, a second power line connector 404, a reference power line connector 406 and an output connector 408. Opamp 440 is powered via the first power line connector 402 and the second power line connector 404, and has its non-inverting terminal coupled via the reference power line connector 406. Its output is coupled to a first IC portion 420 via an internal power line 422, from which a feedback loop 442 runs back to the inverting input of the opamp 440. Optionally, IC 400 has a second circuit portion 430 that can be directly connected to the power supply via the first power line connector 402 and the second power line connector 404. This has the advantage that only circuit portions involved with the generation of output signals via output connector 408 have to be connected to the voltage generator, for example opamp 440, which reduces the load on the voltage generator, which in such a constellation does not have to compensate for current fluctuations originating from the second circuit portion 430. It will be obvious to those skilled in the art that, although not explicitly shown in FIGS. 2 and 3, such a partitioning can also be applied to the IC modules 220 of IC arrangement 200, that is the IC modules 220 being partitioned in a IC module portion being coupled to the voltage generator, for example an opamp 240 or the combination of voltage source 342 and transistor 344 or equivalents thereof, and a IC module portion being directly coupled to the second power line 204, to reduce the load on the voltage generator.

IC 400 can be used as a standalone device, for example a driver IC, but can also be used as a discrete building block to form an IC arrangement 200 of the present invention by interconnecting a number of ICs 400.

Application of the present invention is particularly useful in combination with a matrix array device, because, as explained in the detailed description of FIG. 1, such devices can suffer from current fluctuations, especially when the device covers a large area, which means that the capacitances are large and large currents may arise, and/or when an insulating substrate, for example glass is used, which means that the row and column conductors are the only main path for those currents to leak away through. Such a combination is shown in FIG. 5, where matrix array device 500 includes a first set of conductors 520a-d, and a second set of intercrossing conductors 540a-d, which are used to drive matrix array elements 560. Typically, one of the two sets will form the row conductors and the other set will form the column conductors of the matrix array device 500, which may be a passive matrix LCD, a thin-film transistor (TFT)-LCD, a polymer or organic based LED display, a sensor device or another known matrix array based device, with a matrix array element 560 being a LC pixel as shown in FIG. 1, a sensor or another matrix array element known to those skilled in the art. The first set of conductors 520a-d is coupled to a first IC arrangement, which is an IC arrangement 200 of the present invention. The power lines and the voltage generator have been omitted from the IC arrangement 200 in FIG. 5 for reasons of clarity only. Thus, artefacts in the functioning of the matrix array device 500 originating from current fluctuations on the first set of conductors 520a-d will be suppressed by the voltage generators coupled to the reference power lines of IC modules 220a-d.

The second set of conductors 540a-d is coupled to a second IC arrangement 1200 having a plurality of IC modules 1220a-1220d. The second IC arrangement 1200 may be an IC arrangement according to the present invention, but this is not necessary. The first and second IC arrangements 200 and 1200 may be integrated into the matrix array device using the same technology for constructing the IC arrangements 200 and 1200 as used for constructing the matrix array elements 560, for example by using thin-film transistors. Alternatively, the first and second IC arrangements 200 and 1200 may be separate, discrete devices that may be built from discrete ICs, for example an IC 400 as shown in FIG. 4 and described by its detailed description, which are bonded to the matrix array device 500 by means of known bonding techniques. The IC modules 220a-d and 1220a-d in respective IC arrangements 200 and 1200 may be any known row or column driver circuits, and may be arranged to drive a plurality of row or column conductors rather than drive a single row or column conductor.

It is emphasized that the advantages provided by the IC arrangement of the present invention extend into the whole matrix array device 500, because the matrix array device 500 will exhibit improved output characteristics, for example a more stable or better-defined picture in the case of display devices, which will improve the marketability of such a device.

FIG. 6 shows an electronic device 600 according to the present invention, for example a television, a monitor or a battery-powered device including a matrix array device like a TFT-LCD. Electronic device 600 includes is an IC arrangement 200, with the outputs 224a and 224b of respective IC modules 220a and 220b coupled to an application 640 that is controlled by the signals provided through outputs 224a and 224b. Application 640 may be a matrix array device, but this is not necessary, any application that uses IC arrangement 200 to obtain a reference voltage and that suffers from artefacts induced by power fluctuations along outputs 224a and 224b can exhibit an improved performance by using an IC arrangement 200 of the present invention.

Electronic device 600 further has a power supply arrangement 620 that powers the IC arrangement 200 via the first power line 202 and the second power line 204. The power supply arrangement 620 includes a voltage source 622 for providing reference power line 206 of IC arrangement 200 with a small, preferably negligible current for providing the control terminals of the voltage generators, for example opamps 240a and 240b, with a substantially identical reference voltage. Voltage source 622 can be realized by well-known techniques, which will not be discussed any further.

It is emphasized that even though the voltage generators in IC arrangement 200 are shown separate from IC modules 220a and 220b, they may also be integrated into those modules without departing from the scope of the invention.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

1. An integrated circuit arrangement comprising:
a plurality of integrated circuit modules;
a first power line;
a second power line;
a reference power line;
an integrated circuit module from the plurality of circuit modules comprising:
an internal power line; and
a circuit module portion coupled between the first power line and the internal power line;
the integrated circuit arrangement further comprising a voltage generator coupled between the first power line and the second power line, the voltage generator having a control terminal coupled to the reference power line and an output coupled to the internal power line.

2. An integrated circuit arrangement as claimed in claim 1, wherein the integrated circuit module from the plurality of integrated circuit modules further comprises a second circuit module portion coupled between the first power line and the second power line.

3. An integrated circuit arrangement as claimed in claim 1, wherein the voltage generator comprises an operational amplifier having a non-inverting input comprising the control terminal and an inverting input coupled to the internal power line.

4. An integrated circuit arrangement as claimed in claim 1, wherein the voltage generator comprises:
a current source coupled between the first power line and the internal power line; and
a transistor coupled between the internal power line and the second power line, the transistor having a gate comprising the control terminal.

5. An integrated circuit, comprising:
a first power line connector;
a second power line connector;
a reference power line connector;
an internal power line;
a circuit portion coupled between the first power line connector and the internal power line; and
a voltage generator coupled between the first power line connector and the second power line connector, the voltage generator having a control terminal coupled to the reference power line connector and an output coupled to the internal power line.

6. A matrix array device comprising:
a first set of conductors;
a second set of conductors, the conductors from the second set of conductors being substantially perpendicularly oriented to the conductors from the first set of conductors;
a plurality of matrix elements, each matrix element from the plurality of matrix elements being coupled between a conductor from the first set of conductors and a conductor from the second set of conductors; and
a first integrated circuit arrangement comprising:
a plurality of integrated circuit modules;
a first power line;
a second power line;
a reference power line;
an integrated circuit module from the plurality of circuit modules comprising:
an internal power line; and
a circuit module portion coupled between the first power line and the internal power line, the circuit portion having an output coupled to a conductor from the first set of conductors;
the first integrated circuit arrangement further comprising a voltage generator coupled between the first power line and the second power line, the voltage generator having a control terminal coupled to the reference power line and an output coupled to the internal power line.

7. A matrix array device as claimed in claim 6, further comprising a second integrated circuit arrangement, the second integrated circuit arrangement comprising:
a plurality of integrated circuit modules;
a first power line;
a second power line;
a reference power line;
an integrated circuit module from the plurality of circuit modules comprising:
an internal power line; and
a circuit portion coupled between the first power line and the internal power line, the circuit portion having an output coupled to a conductor from the second set of conductors;
the second integrated circuit arrangement further comprising a voltage generator coupled between the first power line and the second power line, the voltage generator having a control terminal coupled to the reference power line and an output coupled to the internal power line.

8. A matrix array device as claimed in claim 6, wherein the matrix array device is a display device.

9. An electronic device comprising the integrated circuit arrangement of claim 1 and having power supply means coupled to the first power line, the second power line and the reference power line of the integrated circuit arrangement.

10. An electronic device as claimed in claim 9, the electronic device further comprising a matrix array device, the matrix array device comprising:
a first set of conductors;
a second set of conductors, the conductors from the second set of conductors being substantially perpendicularly oriented to the conductors from the first set of conductors,
a plurality of matrix elements, each matrix element from the plurality of matrix elements being coupled between a conductor from the first set of conductors and a conductor from the second set of conductors, at least one of the conductors from the first set of conductors or the second set of conductors being coupled to an integrated circuit module from the plurality of integrated circuit modules.
